(19) United States
(12) Patent Application Publication
(10) Pub. No.: US 2025/0054852 A1
(43) Pub. Date: Feb. 13, 2025

(54) COMBINATION-TYPE SEMICONDUCTOR PACKAGE FOR IMPROVING PACKAGE RELIABILITY

(71) Applicant: Samsung Electronics Co., Ltd., Suwon-si (KR)

(72) Inventor: Chulho Jung, Suwon-si (KR)

(21) Appl. No.: 18/676,836

(22) Filed: May 29, 2024

(30) Foreign Application Priority Data
Aug. 10, 2023 (KR) 10-2023-0105149

(51) Int. Cl. H01L 23/498; H01L 23/00; H01L 23/31; H01L 23/48; H01L 25/065

(52) U.S. Cl. CPC H01L 23/49833; H01L 23/3128; H01L 23/3135; H01L 23/481; H01L 24/16; H01L 24/32; H01L 24/73; H01L 25/0652; H01L 25/0655; H01L 2224/16145; H01L 2224/16225; H01L 2224/32225; H01L 2224/73204; H01L 2924/1815

(57) ABSTRACT

A combination-type semiconductor package includes a wiring plate such as a package substrate, a redistribution structure, and an interposer or a combination thereof. A package element is mounted on the wiring plate, a delamination-preventing layer covers the package element, and a package molding layer encapsulates the package element and the delamination-preventing layer on the wiring plate. The delamination-preventing layer prevents delamination between the package element and the package molding layer.

### CROSS-REFERENCE TO RELATED APPLICATION

This application is based on and claims priority under 35 U.S.C. § 119 to Korean Patent Application No. 10-2023-0105149, filed on Aug. 10, 2023, in the Korean Intellectual Property Office, the disclosure of which is incorporated by reference herein in its entirety.

### BACKGROUND

The inventive concept relates to a semiconductor package, and more particularly, to an integrated (or combination-type) semiconductor package having improved reliability.

As electronic products become multi-functional, have increased capacities, and are reduced in size, combination-type semiconductor packages, in which two or more semiconductor chips or two or more semiconductor packages are integrated with each other, have been proposed. In the combination-type semiconductor packages, package components may be delaminated from each other or have cracks occur in the package components. This may deteriorate package reliability.

### SUMMARY

The inventive concept provides a combination-type semiconductor package with improved package reliability.

According to an aspect of the inventive concept, there is provided a combination-type semiconductor package including a wiring plate including at least one of a package substrate, a redistribution structure, and an interposer substrate, a package element mounted on the wiring plate, a delamination-preventing layer covering the package element, and a package molding layer configured to encapsulate the package element and the delamination-preventing layer on the wiring plate, wherein the delamination-preventing layer prevents delamination between the package element and the package molding layer.

According to another aspect of the inventive concept, there is provided a combination-type semiconductor package including a package substrate, an interposer substrate mounted on the package substrate, a first package element mounted on the interposer substrate, the first package element including a first semiconductor chip including a first chip body, a second package element mounted on the interposer substrate and spaced apart from the first package element, the second package element including a semiconductor package that includes a second semiconductor chip comprising a second chip body and a body molding layer covering the second chip body, a delamination-preventing layer covering the body molding layer of the second package element, and a package molding layer configured to encapsulate the first package element, the delamination-preventing layer, and the second package element on the interposer substrate, wherein the delamination-preventing layer prevents delamination between the body molding layer and the package molding layer.

According to another aspect of the inventive concept, there is provided a combination-type semiconductor package including a wiring plate including at least one of a package substrate, a redistribution structure, and an interposer substrate, a first package element mounted on the wiring plate, the first package element including a first semiconductor chip including a first chip body, a second package element mounted on the wiring plate and spaced apart from the first package element, the second package element including a second semiconductor chip including a second chip body, a delamination-preventing layer covering at least one of the first package element and the second package element, and a package molding layer configured to encapsulate the first package element, the delamination-preventing layer, and the second package element on the wiring plate, wherein the delamination-preventing layer prevents delamination between the first and second chip bodies and the package molding layer.

Other aspects of the inventive concept are directed to methods of manufacturing a combination-type semiconductor package including providing a delamination-preventing layer, on a package element on a wiring plate, and a package molding layer configured to encapsulate the first package element, wherein the delamination-preventing layer prevents delamination between the first and second chip bodies and the package molding layer.

### BRIEF DESCRIPTION OF THE DRAWINGS

Embodiments will be more clearly understood from the following detailed description taken in conjunction with the accompanying drawings in which:

FIG. 1 is a plan view of a combination-type semiconductor package according to an embodiment;

FIG. 2 is a cross-sectional view of the combination-type semiconductor package taken along line II-II′ of FIG. 1;

FIG. 3 is an enlarged cross-sectional view illustrating a second chip body constituting a second package element of FIG. 2;

FIG. 4 is an enlarged cross-sectional view illustrating the second package element of FIG. 2;

FIG. 5 is an enlarged cross-sectional view illustrating a second package element of a combination-type semiconductor package according to an embodiment;

FIGS. 6 to 14 are cross-sectional views for explaining a method of manufacturing a combination-type semiconductor package, according to an embodiment;

FIG. 15 is a cross-sectional view illustrating a combination-type semiconductor package according to an embodiment;

FIG. 16 is a cross-sectional view illustrating a combination-type semiconductor package according to an embodiment;

FIG. 17 is a cross-sectional view illustrating a combination-type semiconductor package according to an embodiment;

FIG. 18 is a cross-sectional view illustrating a combination-type semiconductor package according to an embodiment; and

FIG. 19 is a cross-sectional view illustrating a combination-type semiconductor package according to an embodiment.

### DETAILED DESCRIPTION OF THE EMBODIMENTS

Hereinafter, an embodiment is described in detail with reference to the accompanying drawings. It should be appreciated that the exemplary embodiments are examples—the inventive concept may be implemented in other embodiments than the examples described herein.

As used herein, details referencing the singular form of an element are likewise applicable the plural forms as well, unless the context clearly indicates otherwise. Use of the singular form should thus be understood to apply to equally to the plural for unless context indicates otherwise. In this specification, the drawings may be exaggerated to more clearly describe the inventive concept. Hereinafter, an X direction may be referred to as a first horizontal direction, and a Y direction may be referred to as a second horizontal direction perpendicular to the first horizontal direction. Hereinafter, a Z direction may refer to a vertical direction perpendicular to a plane created by the X direction (the first horizontal direction) and the Y direction (the second horizontal direction).

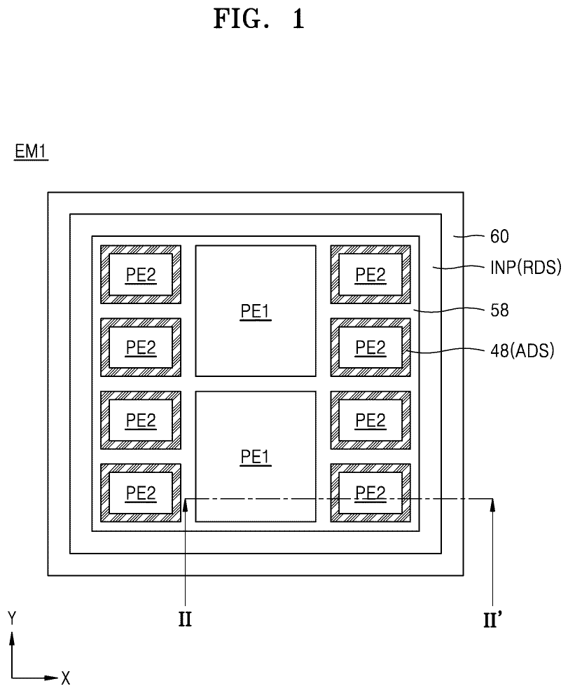

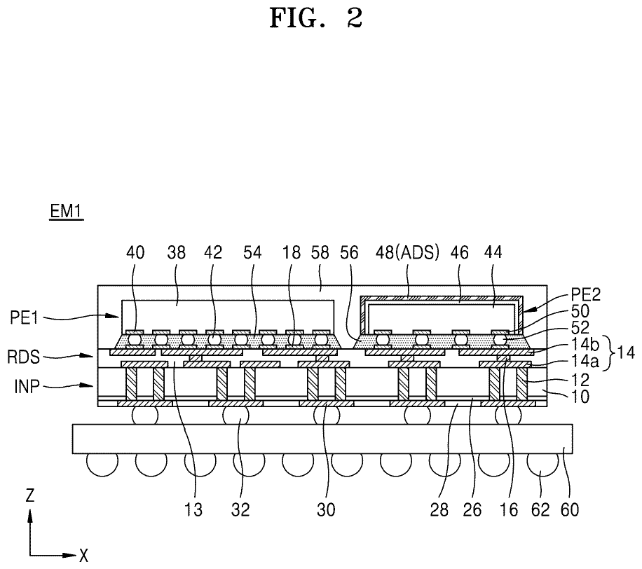

FIG. 1 is a plan view of a combination-type semiconductor package EM1 according to an embodiment. FIG. 2 is a cross-sectional view of the combination-type semiconductor package EM1 taken along line II-II′ of FIG. 1.

Specifically, the combination-type semiconductor package EM1 may include a package substrate 60, an interposer substrate INP, a redistribution structure RDS, one or more first package elements (or devices) PE1, on or more second package elements (or devices) PE2, a delamination-preventing layer 48, and a package molding layer 58.

The first package element PE1 and the second package element PE2 may be disposed on the interposer substrate INP and the redistribution structure RDS. In some embodiments, the first package element PE1 and the second package element PE2 may be disposed on at least one of the interposer substrate INP and the redistribution structure RDS. In some embodiments, the first package element PE1 and the second package element PE2 may be mounted on the package substrate 60 without the interposer substrate INP and the redistribution structure RDS.

A plurality of first package elements PE1, for example, two first package elements PE1, may be arranged in the central portion of the combination-type semiconductor package EM1. The first package element PE1 may include a semiconductor chip including a first chip body in which an integrated circuit is formed. For example, the first package element PE1 may include a logic chip. In some embodiments, the logic chip may be a memory controller chip, a central processing unit (CPU) chip, a graphics processing unit (GPU) chip, or an application processor (AP) chip.

A plurality of second package elements PE2, (eight second package elements PE2 in this example), may be arranged around the first package elements PE1. The second package element PE2 may be a semiconductor package, for example, a memory semiconductor package that includes one or more second chip bodies (e.g., one or more memory chips) and a body molding layer covering the second chip body/bodies, which is described below. It should be appreciated that all of the package elements described herein with respect to all of the different embodiments may include one chip body or a plurality of chip bodies. For brevity and clarity, certain embodiments herein reference a chip body (in the singular) as part of the package element but should be understood to include one or more chip bodies. The more detailed description of other embodiments having that more specifically reference or show a plurality of chip bodies as part of a package element (such as package element PE2 including one or more second chip bodies) should not imply package elements of other embodiments also do not allow for plural chip bodies.

The package molding layer 58 may cover the first package elements PE1 and the second package elements PE2. The package molding layer 58 may be a single homogenous molding layer (for example, formed of the same material throughout I during a formation process performed in the same chamber). The delamination-preventing layer 48 may be disposed on side surfaces of each of the second package elements PE2. The delamination-preventing layer 48 may surround the second package element PE2.

The delamination-preventing layer 48 may include a material layer that prevents delamination (or separation) between the package molding layer 58 and the second package element PE2. The delamination-preventing layer 48 may include an adhesive layer ADS that bonds the package molding layer 58 to the second package element PE2, for example, the body molding layer 46 of the second package element PE2. To identify the second package elements PE2 in FIG. 1, FIG. 1 does not show the delamination-preventing layer 48 disposed on the surface of the second package elements PE2, however, the delamination-preventing layer 48 may fully cover the upper surfaces of the second package elements PE2.

The cross-sectional view of FIG. 2 of the combination-type semiconductor package EM1 (taken along line II-II′ of FIG. 1), illustrates the combination-type semiconductor package EM1 including a package substrate 60, an interposer substrate INP, a redistribution structure RDS, a first package element PE1, a second package element PE2, a delamination-preventing layer 48, and a package molding layer 58.

The package substrate 60 may be a printed circuit board. An external connection terminal 62, for example, an external solder ball, may be disposed on the lower surface of the package substrate 60. In some embodiments, the package substrate 60 may include one or more insulating layers of phenolic resin, epoxy resin, polyimide, or a combination thereof, and have wiring layers (not shown) disposed therein (e.g., between these insulating layers) that are interconnected by conductive vias (not shown) to provide electrical connections (e.g., wires or wiring) between terminals on the upper surface of the package substrate 60 and terminals on the lower surface of the package substrate.

The interposer substrate INP and the redistribution structure RDS may be sequentially disposed on the package substrate 60. The interposer substrate INP and the redistribution structure RDS may each have wirings formed therein (e.g., as described above with respect to package substrate 60) that are electrically connected to each other.

A substrate connection terminal 32, for example, a substrate solder ball, may be disposed on the lower surface of the interposer substrate INP. The interposer substrate INP may include an interposer body 10, a through-via 12, a via isolation insulating layer 26, a via pad insulating layer 28, and a via pad 30.

In some embodiments, the interposer body 10 may be a layer of an organic material, glass, ceramic, or a semiconductor. In some embodiments, the interposer substrate INP may be a layer of silicon (Si). The through-via 12 may fully penetrate the interposer body 10 and may be formed as a through-silicon via. The through-via 12 may include a conductive layer that extends between the upper and lower surfaces of the interposer body 10 to pass through the interposer body 10. The via isolation insulating layer 26 may be an insulating layer that electrically separates through-vias 12 from each other.

The via pad 30 may be formed below the through-via 12. Each via pad 30 may be electrically connected to a corresponding through-via 12 or a corresponding group of through-vias 12. The via pad insulating layer 28 may include an insulating layer that electrically separates via pads 30 from one another. The via pad 30 and the through-via 12 may be formed of one or more conductive materials, such as a conductive metal.

The redistribution structure RDS may include a redistribution insulating layer 13, a redistribution layer 14, a redistribution plug 16, and a redistribution pad 18. Several redistribution layers 14 may be provided, which may include a lower redistribution layer 14a and an upper redistribution layer 14b.

The lower redistribution layer 14a may be attached to the upper surface of the interposer substrate INP and be formed in the lower portion of the redistribution insulating layer 13. The upper redistribution layer 14b may be formed in the upper portion of the redistribution insulating layer 13. The redistribution plug 16 may electrically connect the lower redistribution layer 14a and the upper redistribution layer 14b to each other. The redistribution pad 18 may form a terminal may be electrically connected to the upper redistribution layer 14b. The redistribution insulating layer 13 may be formed of several insulating component layers in which the redistribution layers 14, the redistribution plugs 16, and the redistribution pads 18 may be formed to as a plurality of conductive wirings (e.g. of metal) to electrically interconnect upper terminals of the redistribution structure RDS to lower terminals of the redistribution structure RDS.

The first package element PE1 and the second package element PE2 may be mounted on the redistribution structure RDS. In the embodiment, the redistribution structure RDS may constitute a wiring plate on which the first package element PE1 and the second package element PE2 are mounted.

The first package element PE1 may include a first chip body 38, a first chip pad 40, and a first internal connection terminal 42. The first package element PE1 may include a semiconductor chip, for example, a logic chip. The first chip pad 40 may be located in the lower surface of the first chip body 38. The first chip pad 40 may be electrically connected to the redistribution pad 18 via the first internal connection terminal 42, for example, a first internal solder ball.

The second package element PE2 may be disposed on the redistribution structure RDS, horizontally spaced apart from the first package element PE1 and formed at the same height (e.g., having portions at the same vertical level). For example, the second package element PE2 may be spaced apart from the first package element PE1 in a first horizontal direction (X direction) on the redistribution structure RDS. For example, the second package element and the first package element PE1 may have their first and second internal connection terminals 42, 52 formed at the same height.

The second package element PE2 may include a second chip body 44, a second chip pad 50, a body molding layer 46, and a second internal connection terminal 52. The second package element PE2 may be a semiconductor package that includes the second chip body 44 and the body molding layer 46. It should be appreciated that element 44 of FIG. 2 may be representative of a single second chip body 44 or a plurality of second chip bodies 44 (e.g., as detailed in the example below).

The semiconductor package may be a memory semiconductor package. In some embodiments, the memory semiconductor package may be a high bandwidth memory (HBM) or hybrid memory cube (HMC) semiconductor package. In some embodiments, the memory semiconductor package may be a dynamic random access memory (DRAM) semiconductor package, a static random access memory (SRAM) semiconductor package, a flash semiconductor package, an electrically erasable and programmable read-only memory (EEPROM) semiconductor package, a phase-change random access memory (PRAM) semiconductor package, a magnetic random access memory (MRAM) semiconductor package, or a resistive random access memory (RRAM) semiconductor package.

In some embodiments, the body molding layer 46 may be formed on the top surface and side surfaces of the second chip body 44. In the embodiment, although the body molding layer 46 is shown on the top surface and side surfaces of the second chip body 44, the body molding layer 46 may also be formed on the lower surface of the second chip body 44. When the second package element includes a plurality of second chip bodies 44, the body molding layer 46 may penetrate in between adjacent second chip bodies (e.g., slightly or fully through the space separating adjacent second chip bodies 44).

In some embodiments, the body molding layer 46 may be an epoxy molding compound (EMC). In some embodiments, the body molding layer 46 may include thermosetting resin, such as epoxy resin, thermoplastic resin, such as polyimide, or resin formed by adding reinforcing materials, such as inorganic fillers, to the thermosetting resin or thermoplastic resin. The body molding layer 46 may be formed of the same material throughout (e.g., a homogenous structure that may be formed in the same deposition process).

The second chip pad 50 may be formed in the lower layer of the second chip body 44 with respect to the orientation shown in FIG. 2 (this layer may be described as a top layer of the second chip body when described with respect to the second chip body (e.g., the top layer of a semiconductor chip that forms the second chip body 44)). The second chip pad 50 may form part of the lower surface of the second chip body 44. The second chip pad 50 may be electrically connected to the redistribution pad 18 via the second internal connection terminal 52, for example, a second internal solder ball. The chip pads described herein (like second chip pad 50) may be part of the semiconductor chip in which they are formed and form a terminal of that semiconductor chip to communicate power (voltage, ground) and/or signals to the integrated circuit of that semiconductor chip.

The delamination-preventing layer 48 may cover the second package element PE2. The delamination-preventing layer 48 may be formed on the upper surface and side surfaces of the body molding layer 46. The delamination-preventing layer 48 may be disposed on the body molding layer 46 formed on the top surface and side surfaces of the second chip body 44. In the embodiment, the delamination-preventing layer 48 is described, for convenience, as being an element separate from the second package element PE2, but the delamination-preventing layer 48 may be included as part of the second package element PE2.

The delamination-preventing layer 48 may be and/or include a material layer that prevents delamination between the second package element PE2 and the package molding layer 58 formed subsequently. The delamination-preventing layer 48 may be and/or include an adhesive layer ADS that bonds the second package element PE2 to the package molding layer 58 subsequently formed.

In some embodiments, the delamination-preventing layer 48 may be and/or include a pressure sensitive adhesive layer. In some embodiments, the delamination-preventing layer 48 may include an adhesive polymer. In some embodiments, the delamination-preventing layer 48 may be and/or include an acrylate polymer or a polymethyl-methacrylate (PMMA) polymer.

A first underfill layer 54 and a second underfill layer 56 may be disposed on the lower surface of the first package element PE1 and the lower surface of the second package element PE2, respectively. The first package element PE1 and the second package element PE2 may be attached to the redistribution structure RDS by the first underfill layer 54 and the second underfill layer 56, respectively. Each of the first underfill layer 54 and the second underfill layer 56 may be a non-conductive material layer and may be formed of a material that is different from the material of the package molding layer 58.

The first underfill layer 54 may be formed on the lower surface of the first chip body 38 and between first internal connection terminals 42, above the redistribution structure RDS. The second underfill layer 56 may be formed on the lower surface of the second chip body 44 and between second internal connection terminals 52, above the redistribution structure RDS. In some embodiments, the first underfill layer 54 and the second underfill layer 56 are not formed, and the first underfill layer 54 and the second underfill layer 56 may be replaced with the package molding layer 58.

The package molding layer 58 may be formed on the redistribution structure RDS so as to enclose the first underfill layer 54, the second underfill layer 56, the first package element PE1, the second package element PE2, and the delamination-preventing layer 48. In some embodiments, the package molding layer 58 may be and/or include an EMC. In some embodiments, the package molding layer 58 may be and/or include thermosetting resin, such as epoxy resin, thermoplastic resin, such as polyimide, or resin formed by adding reinforcing materials, such as inorganic fillers, to the thermosetting resin or thermoplastic resin.

The package molding layer 58 may be provided between the first package element PE1 and the second package element PE2 and on the delamination-preventing layer 48. As described above, the delamination-preventing layer 48 may prevent delamination between the second package element PE2, that is, the body molding layer 46 of the second package element PE2, and the package molding layer 58.

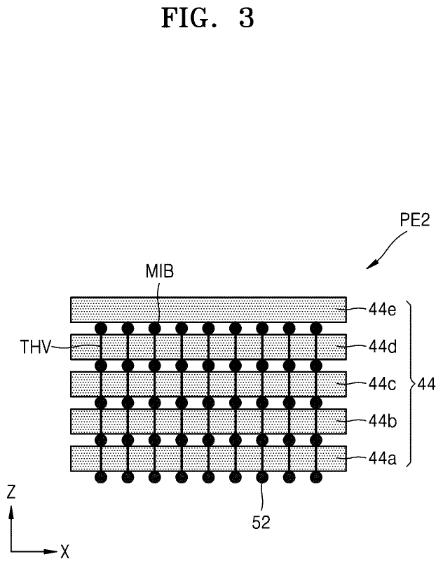

FIG. 3 is an enlarged cross-sectional view illustrating an example where the second package element PE2 of FIG. 2 includes a plurality of chip bodies 44 (44a to 44c).

Specifically, the second package element PE2 may be a memory semiconductor package including the second chip bodies 44. The memory semiconductor package may be, as an example, an HBM or HMC semiconductor package.

The chip bodies 44a to 44c may include a logic chip body and memory chip bodies (hereinafter, the chip body 44a may also be referred to as a logic chip body 44a and the chip bodies 44b to 44c may also be referred to as memory chip bodies 44b to 44c). The logic chip body 44a may constitute a logic chip. The memory chip bodies 44b to 44e may each constitute a memory chip.

In FIG. 3, the logic chip body 44a and the memory chip bodies 44b to 44e are shown as having the same size, for example, having the same width in the X direction. However, the size, for example, the width of the logic chip body 44a in the X direction, may be greater than the size, for example, the width of each of the memory chip bodies 44b to 44e in the X direction. Thicknesses (sizes in the Z direction) may also differ among the chip bodies 44a to 44c, however, it is often the case that all or at least all of the memory chip bodies will have the same thicknesses (e.g., the memory chip bodies may be identical in design and function and thus identical in size).

In FIG. 3, four memory chip bodies 44b to 44e are stacked, but eight or more chip bodies may be stacked as needed. The logic chip body 44a and the memory chip bodies 44b to 44c may be connected to each other via through-vias THV and bumps MIB. The through-vias THV may be electrically and respectively connected to second internal connection terminals 52 formed on one surface of the logic chip body 44a. Each through-via THV may penetrate through (fully extend through) at least the substrate of the chip body in which it is formed and may penetrate through (fully extend through) the entirety of the chip body as well (as shown).

In FIG. 3, the through-vias THV and the bumps MIB are formed entirely in the logic chip body 44a and the memory chip bodies 44b to 44c. However, if necessary, the through-vias THV and the bumps MIB may be formed partially in the logic chip body 44a and the memory chip bodies 44b to 44c.

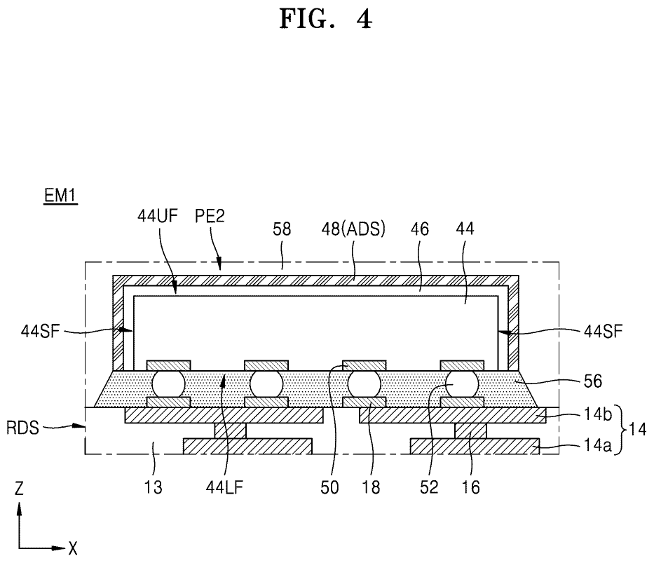

FIG. 4 is an enlarged cross-sectional view illustrating the second package element PE2 of FIG. 2.

Specifically, the descriptions given with reference to FIG. 2 may be briefly repeated or omitted when describing FIG. 4. The second package element PE2 may be disposed on the redistribution structure RDS. The redistribution structure RDS may include a redistribution insulating layer 13, a redistribution layer 14, a redistribution plug 16, and a redistribution pad 18. The redistribution layer 14 may include a lower redistribution layer 14a and an upper redistribution layer 14b.

The second package element PE2 may include one or more second chip bodies 44, a second chip pad 50, a body molding layer 46, a second internal connection terminal 52, and a second underfill layer 56. The second package element PE2 may be a semiconductor package that includes the second chip body/bodies 44 and the body molding layer 46.

The body molding layer 46 may be formed on an upper surface 44UF and a side surface 44SF of the second chip body 44. In the embodiment, although the body molding layer 46 is shown on the upper surface 44UF and the side surface 44SF of the second chip body 44, the body molding layer 46 may also be formed on a lower surface 44LF of the second chip body 44. In some embodiments, the body molding layer 46 may include an EMC. The second chip pad 50 may be electrically connected to the redistribution pad 18 via the second internal connection terminal 52, for example, a second internal solder ball.

A delamination-preventing layer 48 may be disposed on the top surface and side surfaces of the body molding layer 46 constituting the second package element PE2. The delamination-preventing layer 48 may be disposed on the body molding layer 46 formed on the upper surface 44UF and the side surface 44SF of the second chip body 44. In some embodiments, the delamination-preventing layer 48 may be conformally formed on the body molding layer 46, and may have a uniform thickness. The delamination-preventing layer 48 may have a flat outer surface.

The delamination-preventing layer 48 may be and/or include a material layer that prevents delamination between the body molding layer 46 of the second package element PE2 and a package molding layer 58. The delamination-preventing layer 48 may be and/or include an adhesive layer ADS that bonds the body molding layer 46 of the second package element PE2 to the package molding layer 58.

The second chip pad 50 may form part of the lower surface 44LF of the second chip body 44. The second chip pad 50 may be electrically connected to the redistribution pad 18 via the second internal connection terminal 52, for example, a second internal solder ball. The second underfill layer 56 may be formed below the lower surface 44LF of the second chip body 44 and between second internal connection terminals 52, above the redistribution structure RDS. In some embodiments, the second underfill layer 56 may not be formed, and the second underfill layer 56 may be replaced with the package molding layer 58.

In the combination-type semiconductor package EM1 according to an embodiment, the delamination-preventing layer 48 is disposed on the top surface and side surfaces of the body molding layer 46 of the second package element PE2. In the combination-type semiconductor package EM1 according to the inventive concept, the delamination between the second package element PE2, that is, the body molding layer 46 of the second package element PE2, and the package molding layer 58 may be prevented by the delamination-preventing layer 48. Accordingly, the occurrence of cracks in the second internal connection terminal 52, for example, in the second internal solder ball, may be prevented and the package reliability may be improved.

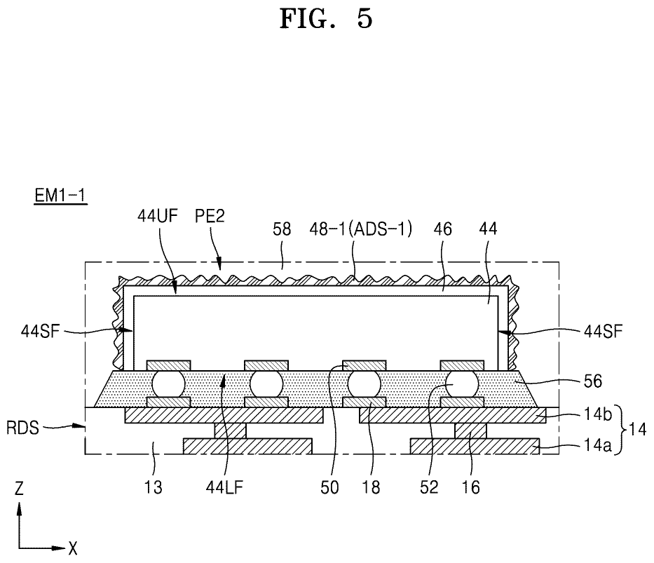

FIG. 5 is an enlarged cross-sectional view illustrating a second package element PE2 of a combination-type semiconductor package EM1-1 according to an embodiment.

Specifically, the combination-type semiconductor package EM1-1 may be almost identical to the combination-type semiconductor package EM1 of FIG. 4, except that a delamination-preventing layer 48-1 of the combination-type semiconductor package EM1-1 has a shape different from that of the combination-type semiconductor package EM1. The descriptions given with reference to FIG. 4 may be briefly given or omitted when describing FIG. 5.

The second package element PE2 may be disposed on the redistribution structure RDS. The redistribution structure RDS may include a redistribution insulating layer 13, a redistribution layer 14, a redistribution plug 16, and a redistribution pad 18. The redistribution layer 14 may include a lower redistribution layer 14a and an upper redistribution layer 14b.

The second package element PE2 may include a second chip body 44, a second chip pad 50, a body molding layer 46, a second internal connection terminal 52, and a second underfill layer 56. The body molding layer 46 may be formed on an upper surface 44UF and a side surface 44SF of the second chip body 44. The delamination-preventing layer 48-1 may be disposed on the top surface and side surfaces of the body molding layer 46 constituting the second package element PE2. The delamination-preventing layer 48-1 may be disposed on the body molding layer 46 formed on the upper surface 44UF and the side surface 44SF of the second chip body 44. In some embodiments, the delamination-preventing layer 48-1 may be formed, on the body molding layer 46, with a non-uniform thickness. The delamination-preventing layer 48-1 may have a concave-convex outer surface formed as a series of protrusions and depressions.

The delamination-preventing layer 48-1 may be and/or include a material layer that prevents delamination between the body molding layer 46 of the second package element PE2 and a package molding layer 58. The delamination-preventing layer 48-1 may be and/or include an adhesive layer ADS-1 that bonds the body molding layer 46 of the second package element PE2 to the package molding layer 58.

When the delamination-preventing layer 48-1 has a corrugated surface (e.g., a concave-convex surface), the body molding layer 46 of the second package element PE2 may be easily bonded to the package molding layer 58. The second underfill layer 56 may be formed below the lower surface 44LF of the second chip body 44 and between second internal connection terminals 52, above the redistribution structure RDS.

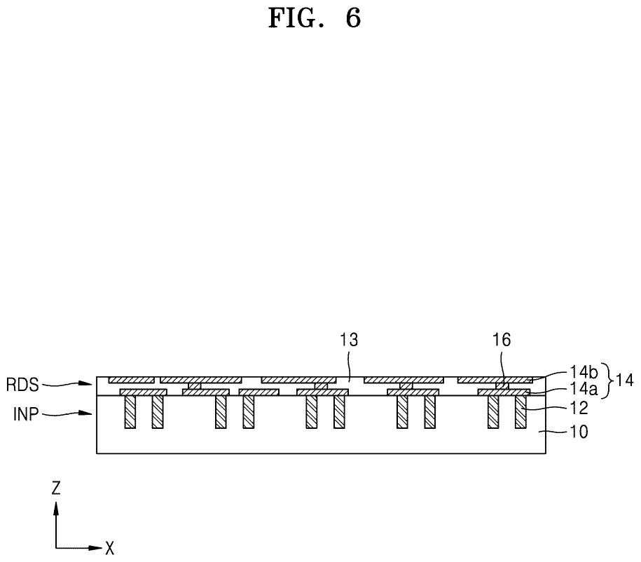

FIGS. 6 to 14 are cross-sectional views for explaining a method of manufacturing a combination-type semiconductor package, according to an embodiment.

Specifically, FIGS. 6 to 14 are provided to explain a method of manufacturing the combination-type semiconductor package EM1 of FIGS. 1 to 4. The descriptions given with reference to FIGS. 1 to 4 may be briefly given or omitted when describing FIGS. 6 to 14. As noted below, it will be apparent that much of the descriptions of this method of manufacturing is also applicable to the semiconductor package EM1-1 of FIG. 5.

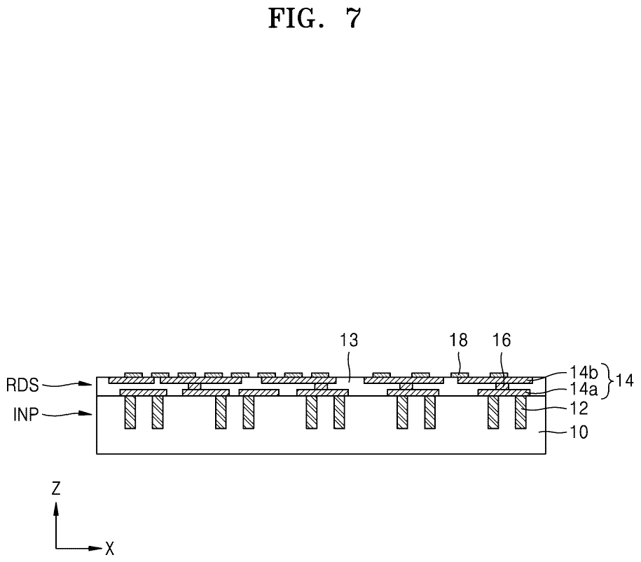

Referring to FIGS. 6 and 7, an interposer substrate INP is prepared, which includes an interposer body 10 and a through-via 12. In some embodiments, the interposer body 10 may be a semiconductor layer, for example, a silicon layer. In an intermediate operation of the manufacturing process shown in FIG. 6, through-vias 12 may be formed to only partially penetrate into the interposer body 10. Each of the through-vias 12 may be a conductor formed from a deposited conductive layer, for example, a metal layer (which may be etched back to reveal the top surface of the interposer body 10 while leaving portions of the conductive layer in holes of the interposer body to form through-vias 12).

Subsequently, a redistribution structure RDS is formed on the interposer substrate INP. The redistribution structure RDS may include a redistribution insulating layer 13, a redistribution layer 14, a redistribution plug 16, and a redistribution pad 18, as shown in FIGS. 6 and 7. The redistribution layer 14 and the redistribution plug 16 may be formed inside the redistribution insulating layer 13.

The redistribution layer 14 may include a lower redistribution layer 14a and an upper redistribution layer 14b. The redistribution plug 16 may electrically connect the lower redistribution layer 14a and the upper redistribution layer 14b to each other. The redistribution pad 18 may be formed on the upper redistribution layer 14b. The redistribution layer 14, the redistribution plug 16, and the redistribution pad 18 may include a conductive layer, such as a metal layer. The lower redistribution layer 14a may be electrically connected to the through-via 12 of the interposer substrate INP.

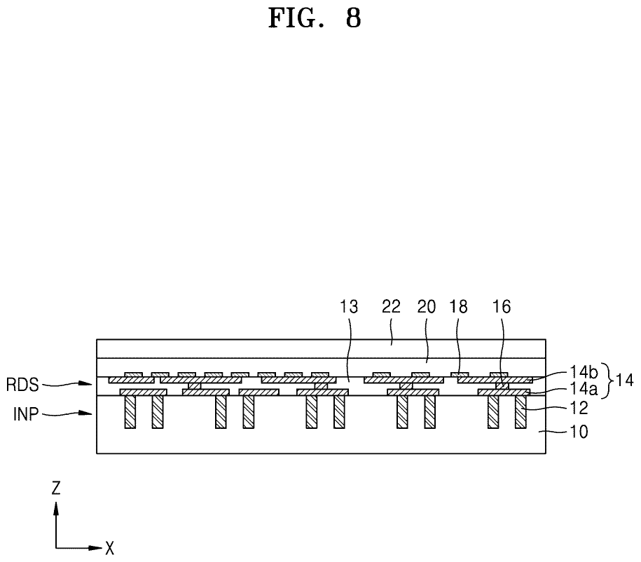

Referring to FIG. 8, a first carrier substrate 22 is attached to the redistribution structure RDS with a first adhesive film 20 therebetween. The first adhesive film 20 may be attached to the upper surface of the redistribution structure RDS. The first adhesive film 20 may be attached to the redistribution pad 18. The first carrier substrate 22 may be entirely attached to the upper surface of the first adhesive film 20.

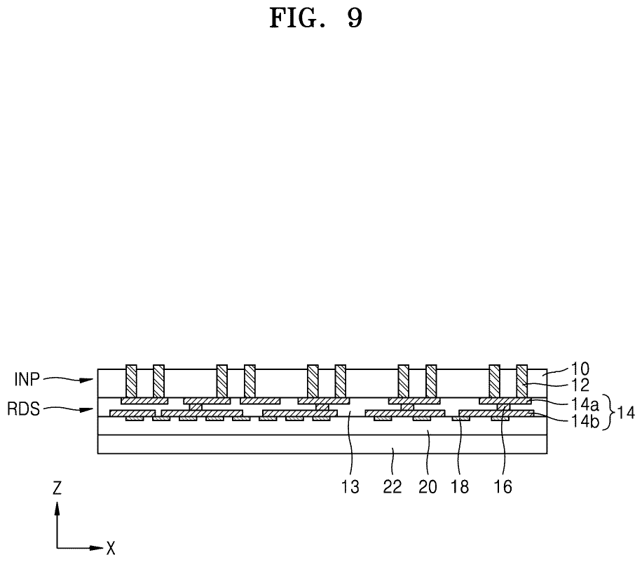

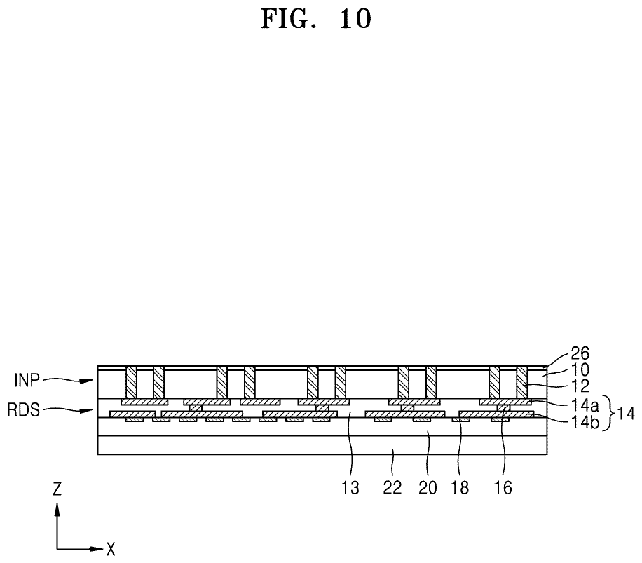

Referring to FIGS. 9 and 10, the structure of FIG. 8 is turned over such that the first carrier substrate 22 is below the interposer substrate INP and the redistribution structure RDS, as shown in FIG. 9. Accordingly, a state, in which the interposer substrate INP is mounted on the redistribution structure RDS, may be formed.

Next, the lower surfaces of the through-vias 12 are set as etch stop points, and the interposer body 10 is ground and flattened. Subsequently, the interposer body 10 is further etched to expose lower portions of the through-vias 12. Accordingly, the through-vias 12 may include through-silicon vias that pass through the interposer body 10, extending between the upper and lower surfaces of the interposer body 10.

As shown in FIG. 10, a via isolation insulating layer 26 is formed between the through-vias 12. The via isolation insulating layer 26 is formed between the through-vias 12 on the lower surface of the interposer body 10 (shown as a top surface in the “upside down” structure of FIG. 10). The via isolation insulating layer 26 may insulate the through-vias 12 from each other. The via isolation insulating layer 26 may be and/or include an oxide layer or a nitride layer.

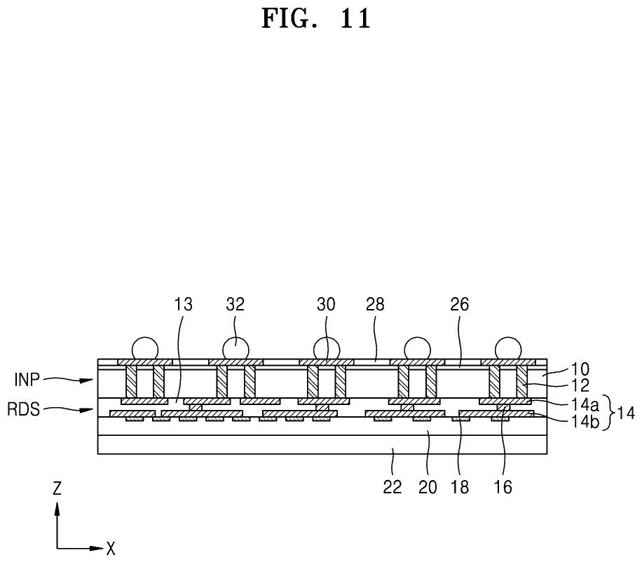

Referring to FIG. 11, a via pad insulating layer 28 and a via pad 30 are formed on the through-vias 12 and the via isolation insulating layer 26. Each via pad 30 may be formed on a corresponding one or a corresponding group of the through-vias 12. The via pad 30 may be formed from a conductive layer, for example, a metal layer. The via pad 30 may be electrically connected to the corresponding through-via(s) 12.

Subsequently, a substrate connection terminal 32, for example, a substrate solder ball, may be formed on a corresponding via pad 30. The substrate connection terminal 32 may be disposed on the lower surface of the interposer substrate INP.

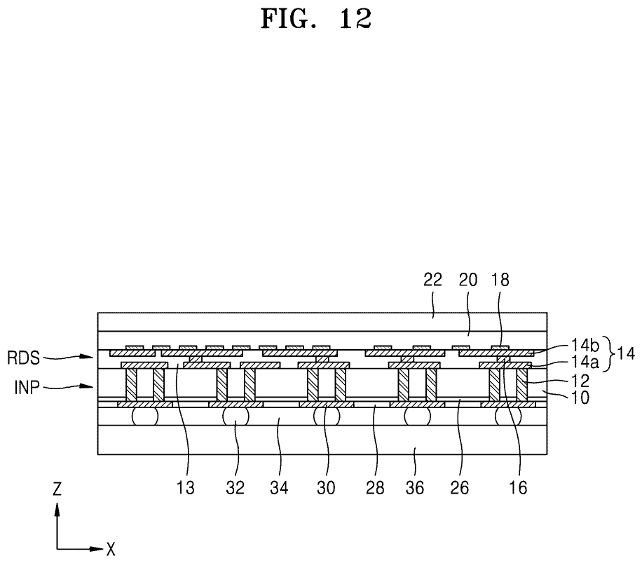

Referring to FIG. 12, a second carrier substrate 36 is attached to the via pad insulating layer 28, the via pad 30, and the substrate connection terminal 32 shown in FIG. 11 with a second adhesive film 34 therebetween, and then the resulting structure is turned over. Accordingly, the second carrier substrate 36 is has a relatively lower position, and the first adhesive film 20 and the first carrier substrate 22 are positioned on the redistribution structure RDS.

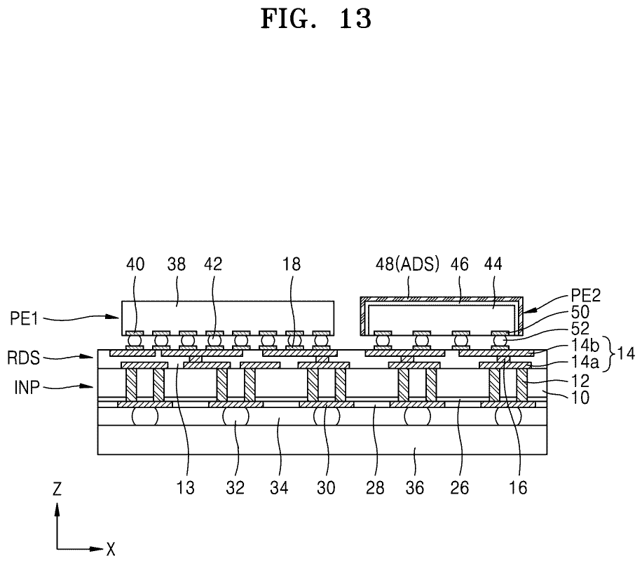

Referring to FIG. 13, the first adhesive film 20 and the first carrier substrate 22 of FIG. 12 are removed. Accordingly, the redistribution pad 18 of the redistribution structure RDS is exposed. Next, a first package element PE1 is prepared. The first package element PE1 may include a semiconductor chip, for example, a logic chip. The first package element PE1 may include a first chip body 38, a first chip pad 40, and a first internal connection terminal 42.

The first package element PE1 is mounted on the redistribution structure RDS. When the first package element PE1 is mounted on the redistribution structure RDS, the first chip pad 40 may be electrically connected to the redistribution pad 18 via the first internal connection terminal 42, for example, a first internal solder ball.

Next, a second package element PE2 is prepared. The second package element PE2 may include on or more second chip bodies 44, a second chip pad 50, a body molding layer 46, and a second internal connection terminal 52. The second package element PE2 may be a semiconductor package that includes the second chip body/bodies 44 and the body molding layer 46. The semiconductor package may be a memory semiconductor package as described herein.

In some embodiments, the body molding layer 46 may be formed on the top surface and side surfaces of the second chip body 44. In some embodiments, the body molding layer 46 may be and/or include an EMC. In some embodiments, the body molding layer 46 may be a layer of thermosetting resin, such as epoxy resin, thermoplastic resin, such as polyimide, or resin formed by adding reinforcing materials, such as inorganic fillers, to the thermosetting resin or thermoplastic resin.

Subsequently, a delamination-preventing layer 48 covers the second package element PE2. This may be performed prior to mounting the second package element PE2 to the redistribution structure RDS. For example, when the second package element PE2 is a semiconductor package, several such semiconductor packages may be formed on a substrate (which may be a carrier substrate later separated from the semiconductor packages or a substrate that forms the substrates of the semiconductor package after it is cut to separate the semiconductor packages from one another). The plurality of semiconductor packages (corresponding to second package element PE2) provided together with the substrate may be subjected to a process to simultaneously cover each of the second package elements PE2 with a delamination-preventing layer 48 as described herein. The semiconductor packages (second package elements PE2) may then be separated from one another by cutting or removing the carrier substrate as noted herein. The delamination-preventing layer 48 may be formed on the upper surface and side surfaces of the body molding layer 46. The delamination-preventing layer 48 may be formed on the body molding layer 46 formed on the top surface and side surfaces of the second chip body 44. The delamination-preventing layer 48 may be and/or include an adhesive layer ADS that bonds the second package element PE2 to the package molding layer 58 that is subsequently formed.

In some embodiments, the delamination-preventing layer 48 may be and/or include a pressure sensitive adhesive layer. In some embodiments, the delamination-preventing layer 48 may be and/or include an adhesive polymer. In some embodiments, the delamination-preventing layer 48 may be and/or include an acrylate polymer or a polymethyl-methacrylate (PMMA) polymer.

The delamination-preventing layer 48 may be formed through various methods. In some embodiments, the second package element PE2 is dipped in a bath that includes a polymer solution containing an adhesive component, and then a solvent is dried. Accordingly, the delamination-preventing layer 48 may be provided. In some embodiments, the second package element PE2 is coated with a polymer solution containing an adhesive component by a spraying method, and then a solvent is dried. Accordingly, the delamination-preventing layer 48 may be provided.

Next, the second package element PE2 covered with the delamination-preventing layer 48 is mounted on the redistribution structure RDS. The second package element PE2 covered with the delamination-preventing layer 48 may be horizontally spaced apart from the first package element PE1 on the redistribution structure RDS. The second chip pad 50 of the second package element PE2 may be electrically connected to the redistribution pad 18 via the second internal connection terminal 52, for example, a second internal solder ball.

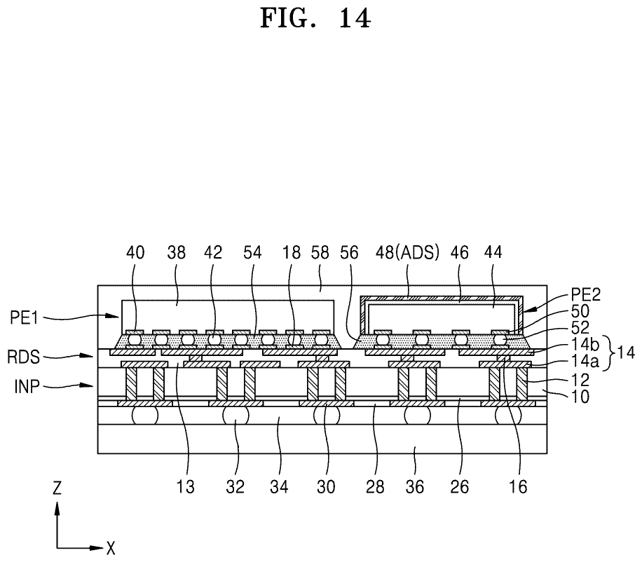

Referring to FIG. 14, a first underfill layer 54 and a second underfill layer 56 may be formed on the lower surface of the first package element PE1 and the lower surface of the second package element PE2, respectively, above the redistribution structure RDS. The first underfill layer 54 may be formed on the lower surface of the first chip body 38 and between first internal connection terminals 42, above the redistribution structure RDS.

The second underfill layer 56 may be formed on the lower surface of the second chip body 44 and between second internal connection terminals 52, above the redistribution structure RDS. In some embodiments, the first underfill layer 54 and the second underfill layer 56 may not be provided.

Subsequently, the package molding layer 58 may be formed on the redistribution structure RDS so as to enclose the first underfill layer 54, the second underfill layer 56, the first package element PE1, the second package element PE2, and the delamination-preventing layer 48. In some embodiments, the package molding layer 58 may include an EMC. In some embodiments, the package molding layer 58 may include thermosetting resin, such as epoxy resin, thermoplastic resin, such as polyimide, or resin formed by adding reinforcing materials, such as inorganic fillers, to the thermosetting resin or thermoplastic resin.

The delamination-preventing layer 48 may prevent delamination between the second package element PE2 and the package molding layer 58, that is, between the body molding layer 46 of the second package element PE2 and the package molding layer 58. Subsequently, the second adhesive film 34 and the second carrier substrate 36 are removed, and the resulting structure is mounted on a package substrate 60. Accordingly, the combination-type semiconductor package EM1 of FIGS. 1 to 4 may be manufactured.

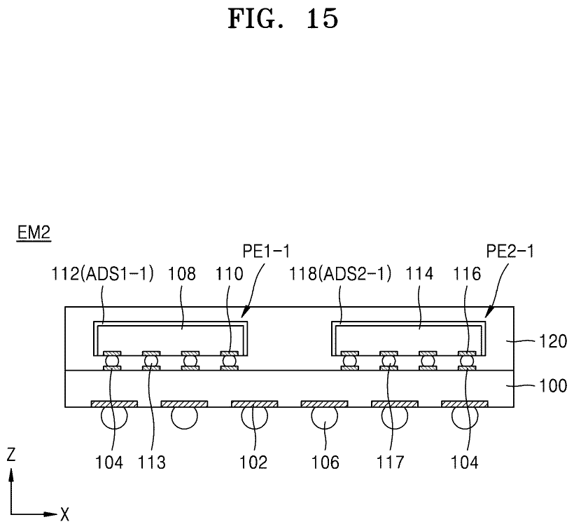

FIG. 15 is a cross-sectional view illustrating a combination-type semiconductor package EM2 according to an embodiment. The structure of the combination-type semiconductor package EM2 may be the same as that of the combination-type semiconductor package EM1 described herein, however, the interposer substrate INP and the redistribution structure RDS of the combination-type semiconductor package EM1 may be omitted. In addition, different package elements PE1-1 and PE2-2 may each have a delamination-preventing layer applied (such alternative also being applicable to the embodiments described above). The package elements PE1-1 and PE2-2 may be respectively the same as package elements PE1 and PE2 as described elsewhere herein. Thus, detailed repetitive description of the structure of the combination-type semiconductor package EM2 and the related method of manufacture may be omitted.

Specifically, the combination-type semiconductor package EM2 may include a package substrate 100, a first package element PE1-1, a first delamination-preventing layer 112, a second package element PE2-1, a second delamination-preventing layer 118, and a package molding layer 120. In the embodiment, the combination-type semiconductor package EM2 is described as including both the first delamination-preventing layer 112 and the second delamination-preventing layer 118 but may include only one of the first delamination-preventing layer 112 and the second delamination-preventing layer 118.

The package substrate 100 may be a printed circuit board. In some embodiments, the package substrate 100 may include one or more insulating layers of phenolic resin, epoxy resin, polyimide, or a combination thereof. A lower substrate pad 102 may be disposed on the lower surface of the package substrate 100. An external connection terminal 106, for example, an external solder ball, may be disposed on the lower substrate pad 102. An upper substrate pad 104 may be disposed on the upper surface of the package substrate 100.

The first package element PE1-1 and the second package element PE2-1 may be mounted on the package substrate 100 and spaced apart from each other in a first horizontal direction (X direction). In the embodiment, the package substrate 100 may constitute a wiring plate on which the first package element PE1-1 and the second package element PE2-1 are mounted.

The first package element PE1-1 may include a first chip body 108, a first chip pad 110, and a first internal connection terminal 113. The first package element PE1-1 may include a first semiconductor chip, for example, a logic chip. The first chip pad 110 may be located in the lower surface of the first chip body 108. The first chip pad 110 may be electrically connected to the upper substrate pad 104 via a first internal connection terminal 113, for example, a first internal solder ball.

The first delamination-preventing layer 112 may be formed on the upper surface and side surfaces of the first package element PE1-1. The first delamination-preventing layer 112 may cover the first package element PE1-1. The first delamination-preventing layer 112 may include a material layer that prevents delamination between the first package element PE1-1 and the package molding layer 120 formed subsequently.

The first delamination-preventing layer 112 may be and/or include a first adhesive layer ADS1-1 that bonds the first package element PE1-1 to the package molding layer 120 formed subsequently. The first delamination-preventing layer 112 may be formed of the same material as the delamination-preventing layer 48 described above with reference to FIGS. 1 to 4.

The second package element PE2-1 may include a second chip body 114, a second chip pad 116, and a second internal connection terminal 117. The second package element PE2-1 may include a second semiconductor chip, for example, a memory chip. The second chip pad 116 may form part of the lower surface of the second chip body 114. The second chip pad 116 may be electrically connected to the upper substrate pad 104 via a second internal connection terminal 117, for example, a second internal solder ball.

The second delamination-preventing layer 118 may be formed on the upper surface and side surfaces of the second package element PE2-1. The second delamination-preventing layer 118 may cover the second package element PE2-1. The second delamination-preventing layer 118 may be and/or include a material layer that prevents delamination between the second package element PE2-1 and the package molding layer 120 formed subsequently.

The second delamination-preventing layer 118 may be and/or include a second adhesive layer ADS2-1 that bonds the second package element PE2-1 to the package molding layer 120 formed subsequently. The second delamination-preventing layer 118 may be formed of the same material as the delamination-preventing layer 48 described above with reference to FIGS. 1 to 4.

The package molding layer 120 may be formed on the package substrate 100 (e.g., connected to and contacting the package substrate 100) so as to enclose the first package element PE1-1, the second package element PE2-2, the first delamination-preventing layer 112, and the second delamination-preventing layer 118. In some embodiments, the package molding layer 120 may include an EMC. In some embodiments, the package molding layer 120 may be and/or include thermosetting resin, such as epoxy resin, thermoplastic resin, such as polyimide, or resin formed by adding reinforcing materials, such as inorganic fillers, to the thermosetting resin or thermoplastic resin.

The package molding layer 120 may be provided between the first package element PE1-1 and the second package element PE2-1 and on the first delamination-preventing layer 112 and the second delamination-preventing layer 118. As described above, the first delamination-preventing layer 112 and the second delamination-preventing layer 118 may prevent the delamination between the first package element PE1-1 and the package molding layer 120 and the delamination between the second package element PE2-1 and the package molding layer 120, respectively.

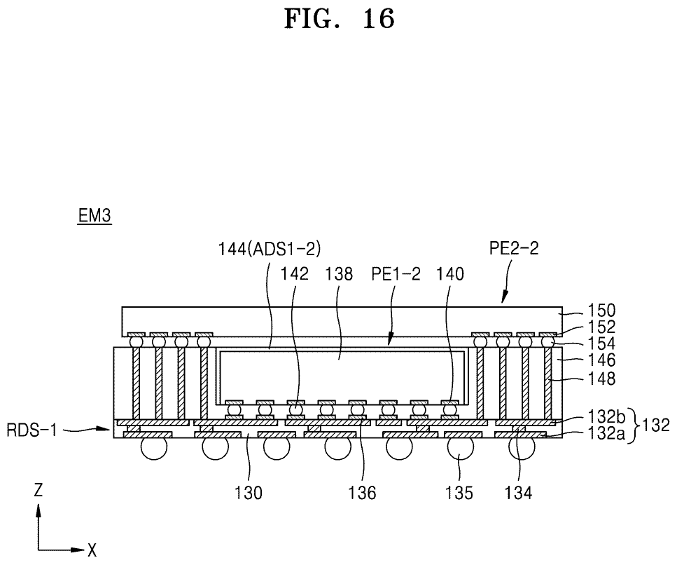

FIG. 16 is a cross-sectional view illustrating a combination-type semiconductor package EM3 according to an embodiment.

Specifically, the combination-type semiconductor package EM3 may include a redistribution structure RDS-1, a first package element PE1-2, a delamination-preventing layer 144, a second package element PE2-2, a package molding layer 146, and a mold via 148.

The redistribution structure RDS-1 may include a redistribution insulating layer 130, a redistribution layer 132, a redistribution plug 134, and a redistribution pad 136. The redistribution layer 132 may include a lower redistribution layer 132a and an upper redistribution layer 132b.

The redistribution plug 134 may electrically connect the lower redistribution layer 132a and the upper redistribution layer 132b to each other. The redistribution pad 136 may be electrically connected to the upper redistribution layer 132b. The redistribution layer 132, the redistribution plug 134, and the redistribution pad 136 may include a conductive layer, such as a metal layer. An external connection terminal 135, for example, an external solder ball, may be disposed on the lower redistribution layer 132a.

The first package element PE1-2 and the second package element PE2-2 may be mounted on the redistribution structure RDS-1 and vertically spaced apart from each other. In the embodiment, the redistribution structure RDS-1 may constitute a wiring plate on which the first package element PE1-2 and the second package element PE2-2 are mounted.

The first package element PE1-2 may include a first chip body 138, a first chip pad 140, and a first internal connection terminal 142. The first package element PE1-2 may include a first semiconductor chip, for example, a logic chip. The first chip pad 140 may be located in the lower surface of the first chip body 138. The first chip pad 140 may be electrically connected to the redistribution pad 136 via the first internal connection terminal 142, for example, a first internal solder ball.

The delamination-preventing layer 144 may be formed on the upper surface and side surfaces of the first package element PE1-2. The delamination-preventing layer 144 may cover the first package element PE1-2. The delamination-preventing layer 144 may be and/or include a material layer that prevents delamination between the first package element PE1-2 and the package molding layer 146 formed subsequently.

The delamination-preventing layer 144 may be and/or include a first adhesive layer ADS1-2 that bonds the first package element PE1-2 to the package molding layer 146 formed subsequently. The delamination-preventing layer 144 may be formed of the same material as the delamination-preventing layer 48 described above with reference to FIGS. 1 to 4.

The first package element PE1-2 including the delamination-preventing layer 144 may be enclosed by the package molding layer 146 on the redistribution structure RDS-1. The delamination-preventing layer 144 may prevent delamination between the package molding layer 146 and the first package element PE1-2. The package molding layer 146 may connect to and contact the redistribution structure RDS-1 to the sides and underneath the first package element PE1-2.

In some embodiments, the package molding layer 146 may be and/or include an EMC. In some embodiments, the package molding layer 146 may be and/or include thermosetting resin, such as epoxy resin, thermoplastic resin, such as polyimide, or resin formed by adding reinforcing materials, such as inorganic fillers, to the thermosetting resin or thermoplastic resin.

The mold via 148 may be formed inside the package molding layer 146. The mold via 148 may include a conductive layer, for example, a metal layer. The mold via 148 may be electrically connected to the upper redistribution layer 132b. In the embodiment, it has been described that the package molding layer 146 is formed, and then the mold via 148 is formed. However, the mold via 148 is formed first, and then the package molding layer 146 may be formed.

The second package element PE2-2 may be vertically stacked on the first package element PE1-2, the package molding layer 146, and the mold via 148. The second package element PE2-2 may include a second chip body 150, a second chip pad 152, and a second internal connection terminal 154. The second package element PE2-2 may include a second semiconductor chip, for example, a memory chip and may be formed as described elsewhere herein (e.g., with respect to FIGS. 1-4). The second chip pad 152 may be located in the lower surface of the second chip body 150. The second chip pad 152 may be electrically connected to the mold via 148 via the second internal connection terminal 154, for example, an internal solder ball.

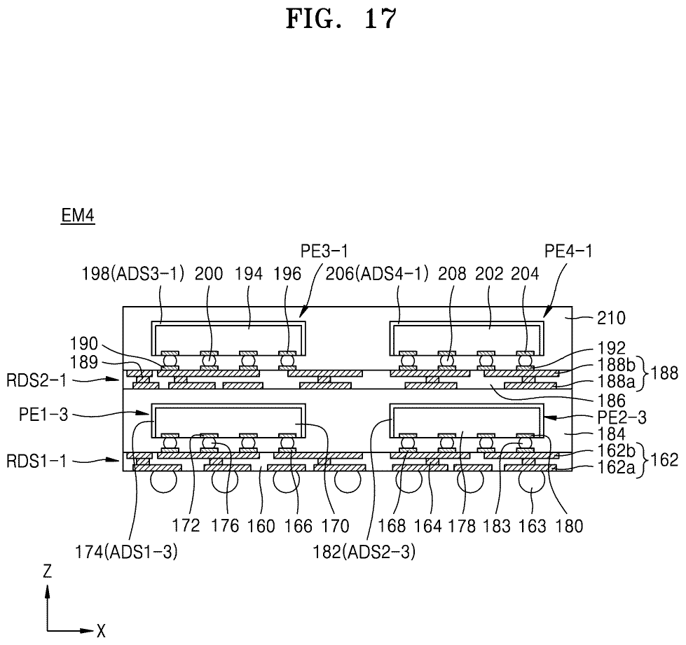

FIG. 17 is a cross-sectional view illustrating a combination-type semiconductor package EM4 according to an embodiment.

Specifically, the combination-type semiconductor package EM4 may include a first redistribution structure RDS1-1, a first package element PE1-3, a first delamination-preventing layer 174, a second package element PE2-3, a second delamination-preventing layer 182, and a first package molding layer 184. In the embodiment, the combination-type semiconductor package EM4 is described as including both the first delamination-preventing layer 174 and the second delamination-preventing layer 182 but may include only one of the first delamination-preventing layer 174 and the second delamination-preventing layer 182.

The first redistribution structure RDS1-1 may include a first redistribution insulating layer 160, a first redistribution layer 162, a first redistribution plug 164, and first redistribution pads 166 and 168. The first redistribution layer 162 may include several component layers including a first lower redistribution layer 162a and a first upper redistribution layer 162b.

The first redistribution plug 164 may electrically connect the first lower redistribution layer 162a and the first upper redistribution layer 162b to each other. The first redistribution pads 166 and 168 may be electrically connected to the first upper redistribution layer 162b. An external connection terminal 163, for example, an external solder ball, may be disposed on the first lower redistribution layer 162a.

The first package element PE1-3 and the second package element PE2-3 may be mounted on the first redistribution structure RDS1-1 and spaced apart from each other in a first horizontal direction (X direction). In the embodiment, the first redistribution structure RDS1-1 may constitute a wiring plate on which the first package element PE1-3 and the second package element PE2-3 are mounted.

The first package element PE1-3 may include a first chip body 170, a first chip pad 172, and a first internal connection terminal 176. The first package element PE1-3 may include a first semiconductor chip, for example, a logic chip. The first chip pad 172 may be located in the lower surface of the first chip body 170. The first chip pad 172 may be electrically connected to the first redistribution pad 166 via the first internal connection terminal 176, for example, a first internal solder ball.

The first delamination-preventing layer 174 may be formed on the upper surface and side surfaces of the first package element PE1-3. The first delamination-preventing layer 174 may cover the first package element PE1-3. The first delamination-preventing layer 174 may be and/or include a material layer that prevents delamination between the first package element PE1-3 and the first package molding layer 184 formed subsequently.

The first delamination-preventing layer 174 may be and/or include a first adhesive layer ADS1-3 that bonds the first package element PE1-3 to the first package molding layer 184 formed subsequently. The first delamination-preventing layer 174 may be formed of the same material as the delamination-preventing layer 48 described above with reference to FIGS. 1 to 4.

The second package element PE2-3 may include a second chip body 178, a second chip pad 180, and a second internal connection terminal 183. The second package element PE2-3 may include a second semiconductor chip, for example, a memory chip. The second chip pad 180 may be located in the lower surface of the second chip body 178. The second chip pad 180 may be electrically connected to the first redistribution pad 168 via the second internal connection terminal 183, for example, a second internal solder ball.

The second delamination-preventing layer 182 may be formed on the upper surface and side surfaces of the second package element PE2-3. The second delamination-preventing layer 182 may cover the second package element PE2-3. The second delamination-preventing layer 182 may be and/or include a material layer that prevents delamination between the second package element PE2-3 and the first package molding layer 184 formed subsequently.

The second delamination-preventing layer 182 may include a second adhesive layer ADS2-3 that bonds the second package element PE2-3 to the first package molding layer 184 formed subsequently. The second delamination-preventing layer 182 may be formed of the same material as the delamination-preventing layer 48 described above with reference to FIGS. 1 to 4.

The first package molding layer 184 may be formed on and contact the first redistribution structure RDS1-1 so as to enclose the first package element PE1-3, the second package element PE2-3, the first delamination-preventing layer 174, and the second delamination-preventing layer 182.

In some embodiments, the first package molding layer 184 may be an EMC. In some embodiments, the first package molding layer 184 may be and/or include thermosetting resin, such as epoxy resin, thermoplastic resin, such as polyimide, or resin formed by adding reinforcing materials, such as inorganic fillers, to the thermosetting resin or thermoplastic resin.

Th first package molding layer 184 may be provided between the first package element PE1-3 and the second package element PE2-3 and on the first delamination-preventing layer 174 and the second delamination-preventing layer 182. As described above, the first delamination-preventing layer 174 and the second delamination-preventing layer 182 may prevent the delamination between the first package element PE1-3 and the first package molding layer 184 and the delamination between the second package element PE2-3 and the first package molding layer 184, respectively.

In the combination-type semiconductor package EM4, a second redistribution structure RDS2-1 may be mounted on the first package molding layer 184 including the first package element PE1-3 and the second package element PE2-3. The second redistribution structure RDS2-1 may include a second redistribution insulating layer 186, a second redistribution layer 188, a second redistribution plug 189, and second redistribution pads 190 and 192. The second redistribution layer 188 may include a second lower redistribution layer 188a and a second upper redistribution layer 188b.

The second redistribution plug 189 may electrically connect the second lower redistribution layer 188a and the second upper redistribution layer 188b to each other. The second redistribution pads 190 and 192 may be electrically connected to the second upper redistribution layer 188b.

In the combination-type semiconductor package EM4, a third package element PE3-1 and a fourth package element PE4-1 may be mounted on the second redistribution structure RDS2-1 and spaced part from each other in the first horizontal direction (X direction). In the embodiment, the second redistribution structure RDS2-1 may constitute a wiring plate on which the third package element PE3-1 and the fourth package element PE4-1 are mounted.

The third package element PE3-1 may include a third chip body 194, a third chip pad 196, and a third internal connection terminal 200. The third package element PE3-1 may include a third semiconductor chip, for example, a logic chip. The third chip pad 196 may be located in the lower surface of the third chip body 194. The third chip pad 196 may be electrically connected to the second redistribution pad 190 via the third internal connection terminal 200, for example, a third internal solder ball.

A third delamination-preventing layer 198 may be formed on the upper surface and side surfaces of the third package element PE3-1. The third delamination-preventing layer 198 may cover the third package element PE3-1. The third delamination-preventing layer 198 may include a material layer that prevents delamination between the third package element PE3-1 and a second package molding layer 210 formed subsequently.

The third delamination-preventing layer 198 may include a third adhesive layer ADS3-1 that bonds the third package element PE3-1 to the second package molding layer 210 formed subsequently. The third delamination-preventing layer 198 may include the same material as the delamination-preventing layer 48 described above with reference to FIGS. 1 to 4.

The fourth package element PE4-1 may include a fourth chip body 202, a fourth chip pad 204, and a fourth internal connection terminal 208. The fourth package element PE4-1 may include a fourth semiconductor chip, for example, a memory chip. The fourth chip pad 204 may be located in the lower surface of the fourth chip body 202. The fourth chip pad 204 may be electrically connected to the second redistribution pad 192 via the fourth internal connection terminal 208, for example, a fourth internal solder ball.

A fourth delamination-preventing layer 206 may be formed on the upper surface and side surfaces of the fourth package element PE4-1. The fourth delamination-preventing layer 206 may cover the fourth package element PE4-1. The fourth delamination-preventing layer 206 may be and/or include a material layer that prevents delamination between the fourth package element PE4-1 and the second package molding layer 210 formed subsequently.

The fourth delamination-preventing layer 206 may be and/or include a fourth adhesive layer ADS4-1 that bonds the fourth package element PE4-1 to the second package molding layer 210 formed subsequently. The fourth delamination-preventing layer 206 may be formed of the same material as the delamination-preventing layer 48 described above with reference to FIGS. 1 to 4.

In the embodiment, the combination-type semiconductor package EM4 is described as including both the third delamination-preventing layer 198 and the fourth delamination-preventing layer 206 but may include only one of the third delamination-preventing layer 198 and the fourth delamination-preventing layer 206.

The second package molding layer 210 may be formed on the second redistribution structure RDS2-1 so as to enclose the third package element PE3-1, the fourth package element PE4-1, the third delamination-preventing layer 198, and the fourth delamination-preventing layer 206.

In some embodiments, the second package molding layer 210 may be an EMC. In some embodiments, the second package molding layer 210 may be and/or include thermosetting resin, such as epoxy resin, thermoplastic resin, such as polyimide, or resin formed by adding reinforcing materials, such as inorganic fillers, to the thermosetting resin or thermoplastic resin.

The second package molding layer 210 may be provided between the third package element PE3-1 and the fourth package element PE4-1 and on the third delamination-preventing layer 198 and the fourth delamination-preventing layer 206. As described above, the third delamination-preventing layer 198 and the fourth delamination-preventing layer 206 may prevent the delamination between the third package element PE3-1 and the second package molding layer 210 and the delamination between the fourth package element PE4-1 and the second package molding layer 210, respectively.

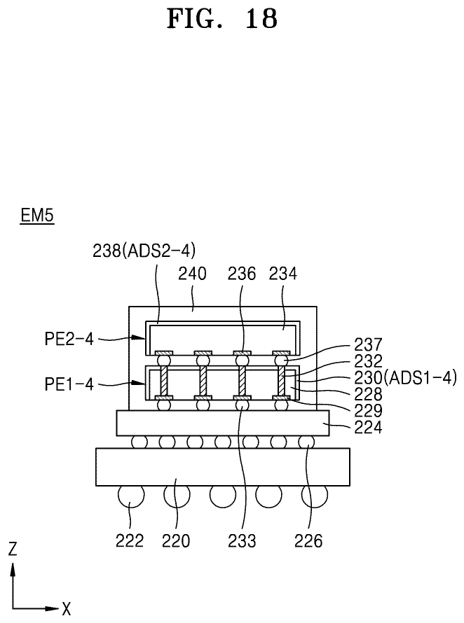

FIG. 18 is a cross-sectional view illustrating a combination-type semiconductor package EM5 according to an embodiment.

Specifically, the combination-type semiconductor package EM5 may include a board substrate 220, a package substrate 224, a first package element PE1-4, a first delamination-preventing layer 230, a second package element PE2-4, a second delamination-preventing layer 238, and a package molding layer 240. In the embodiment, the combination-type semiconductor package EM5 is described as including both the first delamination-preventing layer 230 and the second delamination-preventing layer 238 but may include only one of the first delamination-preventing layer 230 and the second delamination-preventing layer 238.

The package substrate 224 electrically connected to the board substrate 220 via a substrate connection terminal 226, for example, a substrate solder ball, may be mounted above the board substrate 220. An external connection terminal 222, for example, an external solder ball, may be disposed on the lower surface of the board substrate 220.

The first package element PE1-4 and the second package element PE2-4 may be mounted on the package substrate 224 and spaced apart from each other in a vertical direction (Z direction). In the embodiment, the package substrate 224 may constitute a wiring plate on which the first package element PE1-4 and the second package element PE2-4 are mounted.

The first package element PE1-4 may include a first chip body 228, a first chip pad 229, a chip through-via 232, and a first internal connection terminal 233. The first package element PE1-4 may include a first semiconductor chip, for example, a logic chip. The first chip pad 229 may be located in the lower surface of the first chip body 228. The first chip pad 229 and the chip through-via 232 may be electrically connected to the package substrate 224 via the first internal connection terminal 233, for example, a first internal solder ball.

The first delamination-preventing layer 230 may be formed on the upper surface and side surfaces of the first package element PE1-4. The first delamination-preventing layer 230 may cover the first package element PE1-4. The first delamination-preventing layer 230 may be and/or include a material layer that prevents delamination between the first package element PE1-4 and the package molding layer 240 formed subsequently.

The first delamination-preventing layer 230 may be and/or include a first adhesive layer ADS1-4 that bonds the first package element PE1-4 to the package molding layer 240 formed subsequently. The first delamination-preventing layer 230 may be formed of the same material as the delamination-preventing layer 48 described above with reference to FIGS. 1 to 4.

The second package element PE2-4 may be mounted above the first package element PE1-4. The second package element PE2-4 may include a second chip body 234, a second chip pad 236, and a second internal connection terminal 237. The second package element PE2-4 may include a second semiconductor chip, for example, a memory chip. The second chip pad 236 may form part of the lower surface of the second chip body 234. The second chip pad 236 may be electrically connected to the chip through-via 232 of the first package element PE1-4 via the second internal connection terminal 237, for example, a second internal solder ball.

The second delamination-preventing layer 238 may be formed on the upper surface and side surfaces of the second package element PE2-4. The second delamination-preventing layer 238 may cover the second package element PE2-4. The second delamination-preventing layer 238 may be and/or include a material layer that prevents delamination between the second package element PE2-4 and the package molding layer 240 formed subsequently.

The second delamination-preventing layer 238 may be and/or include a second adhesive layer ADS2-4 that bonds the second package element PE2-4 to the package molding layer 240 formed subsequently. The second delamination-preventing layer 238 may be formed of the same material as the delamination-preventing layer 48 described above with reference to FIGS. 1 to 4.

The package molding layer 240 may be formed on and contact the package substrate 224 so as to enclose the first package element PE1-4, the second package element PE2-4, the first delamination-preventing layer 230, and the second delamination-preventing layer 238. In some embodiments, the package molding layer 240 may be an EMC. In some embodiments, the package molding layer 240 may be and/or include thermosetting resin, such as epoxy resin, thermoplastic resin, such as polyimide, or resin formed by adding reinforcing materials, such as inorganic fillers, to the thermosetting resin or thermoplastic resin.

The package molding layer 240 may be provided on the upper and side surfaces of the first package element PE1-4 and the second package element PE2-4, between first and second internal connection terminals 233 and 237, and on the first delamination-preventing layer 230 and the second delamination-preventing layer 238. As described above, the first delamination-preventing layer 230 and the second delamination-preventing layer 238 may prevent the delamination between the first package element PE1-4 and the package molding layer 240 and the delamination between the second package element PE2-4 and the package molding layer 240, respectively.

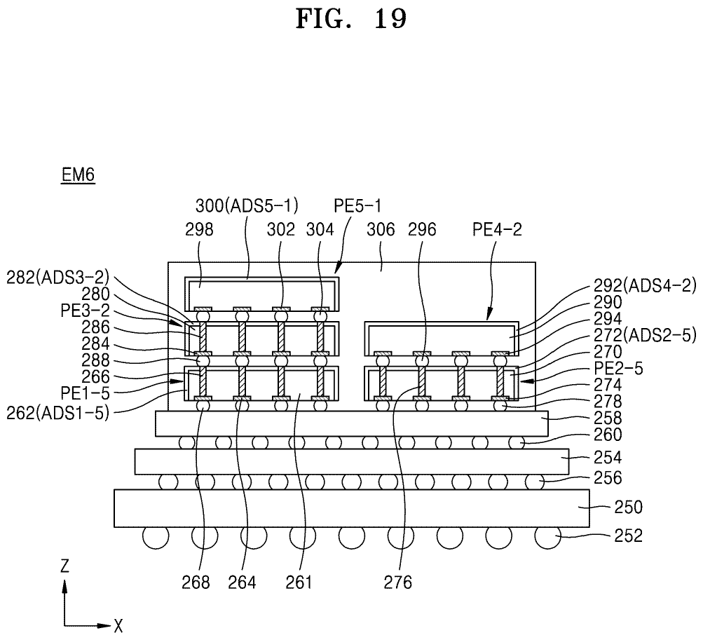

FIG. 19 is a cross-sectional view illustrating a combination-type semiconductor package EM6 according to an embodiment.

Specifically, the combination-type semiconductor package EM6 may include a board substrate 250, first and second package substrates 254 and 258, a first package element PE1-5, a first delamination-preventing layer 262, a second package element PE2-5, and a second delamination-preventing layer 272. In the embodiment, the combination-type semiconductor package EM6 is described as including both the first delamination-preventing layer 262 and the second delamination-preventing layer 272 but may include only one of the first delamination-preventing layer 262 and the second delamination-preventing layer 272.

The first package substrate 254 electrically connected to the board substrate 250 via a first substrate connection terminal 256, for example, a first substrate solder ball may be mounted above the board substrate 250. An external connection terminal 252, for example, an external solder ball, may be disposed on the lower surface of the board substrate 250. The second package substrate 258 electrically connected to the first package substrate 254 via a second substrate connection terminal 260, for example, a second substrate solder ball may be mounted above the first package substrate 254.

The first package element PE1-5 and the second package element PE2-5 may be mounted on the second package substrate 258 and spaced apart from each other in the horizontal direction (X direction). In the embodiment, the second package substrate 258 may constitute a wiring plate on which the first package element PE1-5 and the second package element PE2-5 are mounted.

The first package element PE1-5 may include a first chip body 261, a first chip pad 264, a chip through-via 266, and a first internal connection terminal 268. The first package element PE1-5 may include a first semiconductor chip, for example, a logic chip. The first chip pad 264 may be located in the lower surface of the first chip body 261. The first chip pad 264 and the chip through-via 266 may be electrically connected to the second package substrate 258 via the first internal connection terminal 268, for example, a first internal solder ball.

The first delamination-preventing layer 262 may be formed on the upper surface and side surfaces of the first package element PE1-5. The first delamination-preventing layer 262 may cover the first package element PE1-5. The first delamination-preventing layer 262 may be and/or include a material layer that prevents delamination between the first package element PE1-5 and a package molding layer 306 formed subsequently.

The first delamination-preventing layer 262 may be and/or include a first adhesive layer ADS1-5 that bonds the first package element PE1-5 to the package molding layer 306 formed subsequently. The first delamination-preventing layer 262 may be formed of the same material as the delamination-preventing layer 48 described above with reference to FIGS. 1 to 4.

The second package element PE2-5 may include a second chip body 270, a second chip pad 274, a chip through-via 276, and a second internal connection terminal 278. The second package element PE2-5 may include a second semiconductor chip, for example, a logic chip. The second chip pad 274 may be located in the lower surface of the second chip body 270. The second chip pad 274 and the chip through-via 276 may be electrically connected to the second package substrate 258 via the second internal connection terminal 278, for example, a second internal solder ball.

The second delamination-preventing layer 272 may be formed on the upper surface and side surfaces of the second package element PE2-5. The second delamination-preventing layer 272 may cover the second package element PE2-5. The second delamination-preventing layer 272 may be and/or include a material layer that prevents delamination between the second package element PE2-5 and the package molding layer 306 formed subsequently.

The second delamination-preventing layer 272 may be and/or include a second adhesive layer ADS2-5 that bonds the second package element PE2-5 to the package molding layer 306 formed subsequently. The second delamination-preventing layer 272 may be formed of the same material as the delamination-preventing layer 48 described above with reference to FIGS. 1 to 4.

The combination-type semiconductor package EM6 may include a third package element PE3-2 mounted above the first package element PE1-5 in the vertical direction (Z direction) and a fourth package element PE4-2 mounted above the second package element PE2-5 in the vertical direction (Z direction).

The third package element PE3-2 and the fourth package element PE4-2 may be spaced apart from each other in the first horizontal direction (X direction). The combination-type semiconductor package EM6 may include a third delamination-preventing layer 282 covering the third package element PE3-2 and a fourth delamination-preventing layer 292 covering the fourth package element PE4-2.

The third package element PE3-2 may include a third chip body 280, a third chip pad 284, a chip through-via 286, and a third internal connection terminal 288. The third package element PE3-2 may include a third semiconductor chip, for example, a memory chip. The third chip pad 284 may be located in the lower surface of the third chip body 280. The third chip pad 284 and the chip through-via 286 may be electrically connected to the chip through-via 266 of the first package element PE1-5 via the third internal connection terminal 288, for example, a third internal solder ball.

The third delamination-preventing layer 282 may be formed on the upper surface and side surfaces of the third package element PE3-2. The third delamination-preventing layer 282 may be and/or include a material layer that prevents delamination between the third package element PE3-2 and the package molding layer 306 formed subsequently.

The third delamination-preventing layer 282 may be and/or include a third adhesive layer ADS3-2 that bonds the third package element PE3-2 to the package molding layer 306 formed subsequently. The third delamination-preventing layer 282 may be formed of the same material as the delamination-preventing layer 48 described above with reference to FIGS. 1 to 4.

The fourth package element PE4-2 may include a fourth chip body 290, a fourth chip pad 294, and a fourth internal connection terminal 296. The fourth package element PE4-2 may include a fourth semiconductor chip, for example, a memory chip. The fourth chip pad 294 may be located in the lower surface of the fourth chip body 290. The fourth chip pad 294 may be electrically connected to the chip through-via 276 of the second package element PE2-5 via a fourth internal connection terminal 296, for example, a fourth internal solder ball.

The fourth delamination-preventing layer 292 may be formed on the upper surface and side surfaces of the fourth package element PE4-2. The fourth delamination-preventing layer 292 may be and/or include a material layer that prevents delamination between the fourth package element PE4-2 and the package molding layer 306 formed subsequently.

The fourth delamination-preventing layer 292 may be and/or include a fourth adhesive layer ADS4-2 that bonds the fourth package element PE4-2 to the package molding layer 306 formed subsequently. The fourth delamination-preventing layer 292 may be formed of the same material as the delamination-preventing layer 48 described above with reference to FIGS. 1 to 4.

The combination-type semiconductor package EM6 may include a fifth package element PE5-1 mounted above the third package element PE3-2 in the vertical direction (Z direction) and a fifth delamination-preventing layer 300 covering the fifth package element PE5-1.

The fifth package element PE5-1 may include a fifth chip body 298, a fifth chip pad 302, and a fifth internal connection terminal 304. The fifth package element PE5-1 may include a fifth semiconductor chip, for example, a memory chip. The fifth chip pad 302 may be located in the lower surface of the fifth chip body 298. The fifth chip pad 302 may be electrically connected to the chip through-via 286 of the third package element PE3-2 via the fifth internal connection terminal 304, for example, a fifth internal solder ball.

The fifth delamination-preventing layer 300 may be formed on the upper surface and side surfaces of the fifth package element PE5-1. The fifth delamination-preventing layer 300 may be and/or include a material layer that prevents delamination between the fifth package element PE5-1 and the package molding layer 306 formed subsequently.

The fifth delamination-preventing layer 300 may be and/or include a fifth adhesive layer ADS5-1 that bonds the fifth package element PE5-1 to the package molding layer 306 formed subsequently. The fifth delamination-preventing layer 300 may be formed of the same material as the delamination-preventing layer 48 described above with reference to FIGS. 1 to 4.

In the embodiment, the combination-type semiconductor package EM6 is described as including all of the third delamination-preventing layer 282, the fourth delamination-preventing layer 292, and the fifth delamination-preventing layer 300 but may include only one of the third delamination-preventing layer 282, the fourth delamination-preventing layer 292, and the fifth delamination-preventing layer 300.

The package molding layer 306 may be formed on and contact the second package substrate 258 so as to enclose the first to fifth package elements PE1-5, PE2-5, PE3-2, PE4-2, and PE5-1 and the first to fifth delamination-preventing layers 262, 272, 282, 292, and 300.

In some embodiments, the package molding layer 306 may be an EMC. In some embodiments, the package molding layer 306 may be and/or include thermosetting resin, such as epoxy resin, thermoplastic resin, such as polyimide, or resin formed by adding reinforcing materials, such as inorganic fillers, to the thermosetting resin or thermoplastic resin.

As described above, the first to fifth delamination-preventing layers 262, 272, 282, 292, and 300 may prevent the delamination between the package molding layer 306 and the first to fifth package elements PE1-5, PE2-5, PE3-2, PE4-2, and PE5-1, respectively.

While the inventive concept has been particularly shown and described with reference to embodiments thereof, it will be understood that various changes in form and details may be made therein without departing from the spirit and scope of the inventive concept.

What is claimed is:

1. A combination-type semiconductor package comprising:
a wiring plate comprising at least one of a package substrate, a redistribution structure, and an interposer substrate;
a package element mounted on the wiring plate;
a delamination-preventing layer covering the package element; and
a package molding layer configured to encapsulate the package element and the delamination-preventing layer on the wiring plate,
wherein the delamination-preventing layer prevents delamination between the package element and the package molding layer.

2. The combination-type semiconductor package of claim 1, wherein the package element comprises a semiconductor chip comprising a chip body, and
the delamination-preventing layer prevents delamination between the chip body and the package molding layer.

3. The combination-type semiconductor package of claim 1, wherein the package element comprises a semiconductor package that comprises a chip body and a body molding layer covering the chip body, and
the delamination-preventing layer prevents delamination between the body molding layer and the package molding layer.

4. The combination-type semiconductor package of claim 1, wherein the delamination-preventing layer comprises an adhesive layer that bonds the package element and the package molding layer to each other, and
the adhesive layer comprises polymer.

5. The combination-type semiconductor package of claim 1, wherein the delamination-preventing layer has a corrugated outer surface.

6. The combination-type semiconductor package of claim 1,
wherein the package element is a first package element and the combination-type semiconductor package comprises a second package element, the first package element and the second package element each being mounted on the wiring plate and horizontally spaced apart from each other, and
wherein the delamination-preventing layer covers at least one of the first package element and the second package element.

7. The combination-type semiconductor package of claim 6,
wherein the first package element comprises a first semiconductor chip comprising a first chip body, and
wherein the second package element comprises a semiconductor package that comprises a second semiconductor chip comprising a second chip body and a body molding layer covering the second chip body.

8. The combination-type semiconductor package of claim 6,
wherein the first package element comprises a first semiconductor chip comprising a first chip body, and
wherein the second package element comprises a second semiconductor chip comprising a second chip body.

9. The combination-type semiconductor package of claim 1,
wherein the package element is a first package element and the combination-type semiconductor package comprises a second package element, the first package element and the second package element each being mounted on the wiring plate and vertically spaced apart from each other, and
wherein the delamination-preventing layer covers at least one of the first package element and the second package element.

10. The combination-type semiconductor package of claim 1,
wherein the first package element comprises a first semiconductor chip comprising a first chip body, and
wherein the second package element comprises a second semiconductor chip comprising a second chip body.

11. A combination-type semiconductor package comprising:
a package substrate;
an interposer substrate mounted on the package substrate;
a first package element mounted on the interposer substrate, the first package element comprising a first semiconductor chip comprising a first chip body;
a second package element mounted on the interposer substrate and spaced apart from the first package element, the second package element comprising a semiconductor package that comprises a second semiconductor chip comprising a second chip body and a body molding layer covering the second chip body;
a delamination-preventing layer covering the body molding layer of the second package element; and
a package molding layer configured to encapsulate the first package element, the delamination-preventing layer, and the second package element on the interposer substrate,
wherein the delamination-preventing layer prevents delamination between the body molding layer and the package molding layer.

12. The combination-type semiconductor package of claim 11,
wherein the second chip body semiconductor package comprises a plurality of second semiconductor chips, and
wherein the second semiconductor chips comprise a logic semiconductor chip and a memory semiconductor chip.

13. The combination-type semiconductor package of claim 11,
wherein the first semiconductor chip comprises a logic chip, and
wherein the semiconductor package is a memory semiconductor package.

14. The combination-type semiconductor package of claim 11,
wherein the body molding layer covers a top surface and side surfaces of the second chip body, and
wherein the delamination-preventing layer is disposed on the body molding layer that covers the top surface and side surfaces of the second chip body.

15. The combination-type semiconductor package of claim 11, wherein the delamination-preventing layer comprises an adhesive layer that bonds the body molding layer and the package molding layer to each other.

16. The combination-type semiconductor package of claim 11, wherein the delamination-preventing layer has a corrugated surface.

17. The combination-type semiconductor package of claim 11, further comprising a redistribution structure between the interposer substrate and the first and second package elements.

18. A combination-type semiconductor package comprising:
a wiring plate comprising at least one of a package substrate, a redistribution structure, and an interposer substrate;
a first package element mounted on the wiring plate, the first package element comprising a first semiconductor chip comprising a first chip body;
a second package element mounted on the wiring plate and spaced apart from the first package element, the second package element comprising a second semiconductor chip comprising a second chip body;
a delamination-preventing layer covering at least one of the first package element and the second package element; and
a package molding layer configured to encapsulate the first package element, the delamination-preventing layer, and the second package element on the wiring plate,
wherein the delamination-preventing layer prevents delamination between the first and second chip bodies and the package molding layer.

19. The combination-type semiconductor package of claim 18, further comprising a third package element mounted above and vertically spaced apart from at least one of the first package element and the second package element,
wherein the third package element comprises a third semiconductor chip comprising a third chip body, and
wherein the combination-type semiconductor package further comprises an additional delamination-preventing layer between the third chip body and the package molding layer.

20. The combination-type semiconductor package of claim 19,
wherein the delamination-preventing layer is disposed on a top surface and side surfaces of each of the first and second chip bodies, and
wherein the additional delamination-preventing layer is disposed on a top surface and side surfaces of the third chip body.
